(19) United States
(12) Patent Application Publication
(10) Pub. No.: US 2025/0380584 A1
(43) Pub. Date: Dec. 11, 2025

(54) DISPLAY DEVICE, METHOD OF MANUFACTURING THE SAME, AND ELECTRONIC DEVICE COMPRISING THE SAME

(71) Applicant: Samsung Display Co., LTD., Yongin-si (KR)

(72) Inventors: Jeong Wan HAN, Yongin-si (KR); Hyeong Gyu KIM, Yongin-si (KR); Jae Hun SEO, Yongin-si (KR); Hyun Cheol KIM, Yongin-si (KR); Sang Ho LEE, Yongin-si (KR)

(21) Appl. No.: 19/062,882

(22) Filed: Feb. 25, 2025

(30) Foreign Application Priority Data
Jun. 7, 2024 (KR) 10-2024-0074222

(51) Int. Cl. H10K 59/131; H10K 59/12; H10K 59/122; H10K 71/60; H10K 102/00

(52) U.S. Cl. CPC H10K 59/131; H10K 59/1201; H10K 59/122; H10K 71/60; H10K 2102/351

(57) ABSTRACT

A display device, a method of manufacturing the same, and an electronic device comprising the same are provided. The display device includes a pixel comprising sub-pixel areas, sub-pixel areas including a first sub-pixel area and a second sub-pixel area. The display device includes a semiconductor wafer including a substrate; a bonding conductive layer on the semiconductor wafer; a reflective conductive layer on the bonding conductive layer; and a light emitting element electrically connected to the reflective conductive layer. The bonding conductive layer includes a first bonding conductive layer in the first sub-pixel area and a second bonding conductive layer in the second sub-pixel area. The first bonding conductive layer and the second bonding conductive layer have different thicknesses.

### CROSS-REFERENCE TO RELATED APPLICATION

The present application claims priority to and the benefit of Korean Patent Application No. 10-2024-0074222, filed on Jun. 7, 2024, in the Korean Intellectual Property Office, the entire content of which is incorporated herein by reference.

### BACKGROUND

### 1. Field

Embodiments of the present disclosure relate to a display device, a method of manufacturing the same, and an electronic device comprising the same.

### 2. Discussion

In recent years, the growing interest in information display has spurred continuous research and development in display devices.

Organic light emitting diodes (OLEDs) are active light-emitting type (kind) display elements that offer several advantages, including wide viewing angles, high contrast, low voltage operation (i.e., they are able to be driven at low voltages), lightweight and thin design, and fast response times (speeds).

An organic light emitting diode (OLED) may emit light by (through) electrical signals supplied via multiple conductive lines. These conductive lines may have specific electrical characteristics (intended and/or specified electrical characteristics), such as resistance. If these electrical characteristics (of the conductive lines) are altered (distorted), the reliability of the light emitting element may be compromised (and/or the light emitting element may be damaged).

The above information disclosed in this Background section is only for enhancement of understanding of the background of the disclosure and therefore it may contain information that does not constitute prior art.

### SUMMARY

Aspects of one or more embodiments of the present disclosure are directed to a display device and an electronic device comprising the same in which the reliability of electrical signals provided to the display device can be improved and a method of manufacturing the same.

Aspects of one or more embodiments of the present disclosure are directed to a display device and an electronic device comprising the same in which challenges (e.g., complications or risks of undesired characteristics) in a manufacturing process can be reduced and a method of manufacturing the same.

Aspects of one or more embodiments of the present disclosure is to provide a display device and an electronic device comprising the same with excellent or suitable display quality and a method of manufacturing the same.

Additional aspects will be set forth in part in the description which follows and, in part, will be apparent from the description, or may be learned by practice of the presented embodiments of the disclosure.

According to one or more embodiments of the present disclosure, a display device includes a pixel including sub-pixel areas, the sub-pixel areas including a first sub-pixel area and a second sub-pixel area. The display device includes a semiconductor wafer including a substrate; a bonding conductive layer arranged on the semiconductor wafer; a reflective conductive layer arranged on the bonding conductive layer; and a light emitting element electrically connected to the reflective conductive layer. The bonding conductive layer includes a first bonding conductive layer in the first sub-pixel area and a second bonding conductive layer in the second sub-pixel area. The first bonding conductive layer and the second bonding conductive layer have different thicknesses.

According to one or more embodiments, the display device may further include an interlayer insulating layer covering the reflective conductive layer and arranged between the reflective conductive layer and the light emitting element. The interlayer insulating layer may have different thicknesses in the sub-pixel areas.

According to one or more embodiments, the display device may further include a partition wall arranged on the interlayer insulating layer between the sub-pixel areas.

According to one or more embodiments, the display device may further include a partition wall insulating layer arranged on the partition wall. The partition wall may include silicon.

According to one or more embodiments, the bonding conductive layer may include copper (Cu). The reflective conductive layer may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected from among them. The partition wall insulating layer may include one or more of silicon oxide (SiOₓ), silicon nitride (SiNₓ), titanium oxide (TiOₓ), and/or aluminum oxide (AlₓO_{y}).

According to one or more embodiments, the display device may further include a first insulating layer and a second insulating layer arranged between the partition wall and the interlayer insulating layer and having different widths. That is, the display device may further include the first insulating layer and the second insulating layer (e.g., that are) arranged between the partition wall and the interlayer insulating layer, with the first and second insulating layers having different widths.

According to one or more embodiments, the semiconductor wafer may include a pixel circuit on the substrate. The bonding conductive layer may be electrically connected to the pixel circuit. A via layer may not be interposed between the bonding conductive layer and the semiconductor wafer (e.g., the bonding conductive layer and the semiconductor wafer may be in direct contact with each other).

According to one or more embodiments, the bonding conductive layer and the semiconductor wafer may be coupled to each other by solder bonding or Cu—Cu hybrid bonding.

According to one or more embodiments, the display device may further include a lower conductive layer arranged between the bonding conductive layer and the reflective conductive layer. The reflective conductive layer may include a first reflective conductive layer in the first sub-pixel area and a second reflective conductive layer in the second sub-pixel area. The first reflective conductive layer and the second reflective conductive layer may have the same thickness.

According to one or more embodiments, the semiconductor wafer may be a CMOS (Complementary Metal Oxide Semiconductor) wafer.

According to one or more embodiments, the display device may further include an encapsulation layer arranged on the light emitting element; color filters on the encapsulation layer; and lenses on the color filters. The display device may be an OLEDoS (OLED on Silicon) display device.

A method of manufacturing a display device according to one or more embodiments of the present disclosure includes supplying a bonding assembly including a bonding conductive layer; supplying a semiconductor wafer; coupling the semiconductor wafer and the bonding assembly by the bonding conductive layer; and forming a light emitting element.

According to one or more embodiments, the supplying of the bonding assembly may include forming a first base insulating layer, a second base insulating layer, and a base interlayer insulating layer on a base; forming an interlayer insulating layer to have different thicknesses in some areas by removing at least a portion of the base interlayer insulating layer; and forming a base reflective conductive layer on the interlayer insulating layer. The base reflective conductive layer may be formed after the interlayer insulating layer is formed.

According to one or more embodiments, the supplying of the bonding assembly may further include forming a first reflective conductive layer and a second reflective conductive layer by removing at least a portion of the base reflective conductive layer; forming a lower conductive layer covering the first reflective conductive layer and the second reflective conductive layer; and forming the bonding conductive layer to include a first bonding conductive layer arranged on the first reflective conductive layer and a second bonding conductive layer arranged on the second reflective conductive layer.

According to one or more embodiments, the supplying of the bonding assembly may further include performing a planarization process by removing at least portions of the first bonding conductive layer and the second bonding conductive layer so that upper surfaces of the first bonding conductive layer and the second bonding conductive layer have flat surfaces that coincide with each other (e.g., are substantially coplanar).

According to one or more embodiments, in the coupling the semiconductor wafer and the bonding assembly, the bonding conductive layer and the semiconductor wafer may be coupled to each other by solder bonding or Cu—Cu hybrid bonding.

According to one or more embodiments, the method of manufacturing the display device may further include supplying a partition wall base by performing a back grinding process on the base after the coupling of the semiconductor wafer and the bonding assembly.

According to one or more embodiments, the method of manufacturing the display device may further include forming partition walls that are spaced and/or apart (e.g., spaced apart or separated) from each other and expose the first base insulating layer by removing at least a portion of the partition wall base; forming a partition wall base insulating layer covering the partition walls and the first base insulating layer; exposing the second base insulating layer by etching the partition wall base insulating layer and the first base insulating layer; and exposing the interlayer insulating layer by etching the second base insulating layer.

According to one or more embodiments, the light emitting element may include an anode electrode, an emission structure, and a cathode electrode. The forming the light emitting element may include forming the anode electrode between the partition walls; forming the emission structure on the anode electrode between the partition walls; and forming the cathode electrode covering the emission structure and the cathode electrode.

According to one or more embodiments, the method of manufacturing the display device may further include forming color filters on the light emitting element; and forming lenses on the color filters.

According to one or more embodiments of the present disclosure, an electronic device, may comprise: a processor configured to provide input image data; a display device configured to display an image based on the input image data, the display device including sub-pixel areas; and a power supply configured to supply power to the display device. The display device may comprise: a pixel comprising sub-pixel areas, the sub-pixel areas comprising a first sub-pixel area and a second sub-pixel area; a semiconductor wafer comprising a substrate; a bonding conductive layer on the semiconductor wafer; a reflective conductive layer on the bonding conductive layer; and a light emitting element electrically connected to the reflective conductive layer. The bonding conductive layer may comprise a first bonding conductive layer in the first sub-pixel area and a second bonding conductive layer in the second sub-pixel area. The first bonding conductive layer and the second bonding conductive layer may have different thicknesses.

### BRIEF DESCRIPTION OF THE DRAWINGS

The accompanying drawings, which are included to provide a further understanding of the present disclosure, and are incorporated in and constitute a part of this specification, illustrate embodiments of the present disclosure, and, together with the description, serve to explain principles of the present disclosure. In the drawings,

FIG. 1 is a plan view schematically illustrating a display device according to one or more embodiments of the present disclosure.

FIG. 2 is a cross-sectional view schematically illustrating the display device according to one or more embodiments of the present disclosure.

FIG. 3 is a plan view schematically illustrating a pixel according to one or more embodiments of the present disclosure.

FIG. 4 is a plan view schematically illustrating a pixel according to one or more embodiments of the present disclosure.

FIG. 5 is a plan view schematically illustrating a pixel according to one or more embodiments of the present disclosure.

FIG. 6 is a cross-sectional view schematically illustrating a display device taken along the line A-A′ of FIG. 1, according to one or more embodiments of the present disclosure.

FIGS. 7 and 8 are each a cross-sectional view schematically illustrating a light emitting element according to one or more embodiments of the present disclosure.

FIGS. 9 to 22 are each a cross-sectional view schematically illustrating a process step (e.g., process act or task) of a method of manufacturing a display device according to one or more embodiments of the present disclosure.

FIG. 23 is a block diagram illustrating an electronic device, according to one or more embodiments of the present disclosure.

FIG. 24 is a perspective view illustrating a head-mounted display device as an example of an application of the electronic device of FIG. 23, according to one or more embodiments of the present disclosure.

FIG. 25 is a diagram illustrating the head-mounted display device of FIG. 24 worn by a user, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. “ ” “ ”

As used herein, the singular forms “a,” “an” and “the” are intended to include the plural forms as well, unless the context clearly indicates otherwise.

It will be further understood that the terms “comprise”, “include”, “have”, etc. when used in the disclosure, specify the presence of the stated features, integers, steps, operations, elements, components, and/or combinations of them, but do not preclude the presence or addition of one or more other features, integers, steps, operations, elements, components, and/or combinations thereof. In addition, when a first part such as a layer, film, region, plat, etc. is on a second part, the first part may be not only “directly on” the second part but a third part may intervene between them. Furthermore, in the disclosure, when a first part such as a layer, film, region, plat, etc. is formed on a second part, a direction in which the first part is formed is not limited to an upper direction of the second part, but may include a side or a lower direction of the second part. To the contrary, when a first part such as a layer, film, region, plat, etc. is “under” a second part, the first part may be not only “directly under” the second part, but a third part may intervene between them.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the terms “use,” “using,” and “used” may be considered synonymous with the terms “utilize,” “utilizing,” and “utilized,” respectively.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

The present disclosure relates to a display device, a method of manufacturing the same, and an electronic device comprising the same. Hereinafter, a display device, a method of manufacturing the same, and an electronic device comprising the same according to one or more embodiments will be described with reference to the attached drawings.

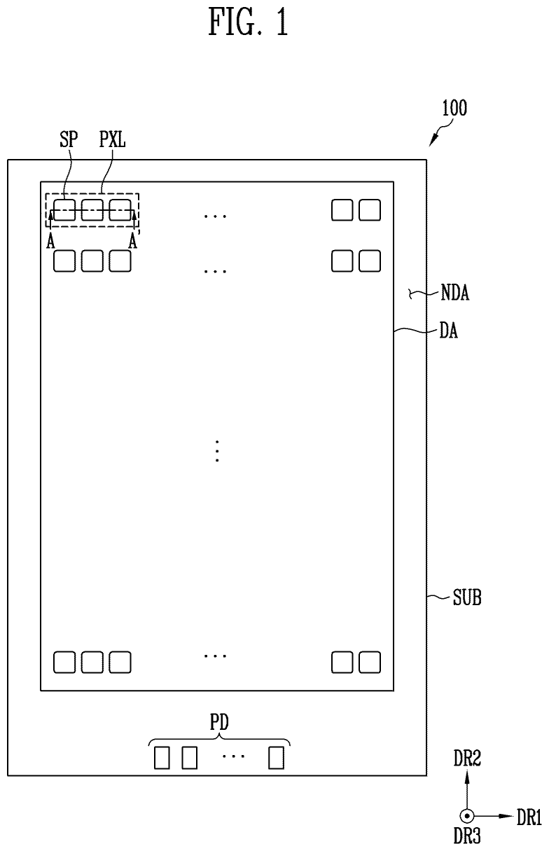

FIG. 1 is a plan view schematically illustrating a display device according to one or more embodiments of the present disclosure.

Referring to FIG. 1, a display device 100 according to one or more embodiments may be configured to emit light.

The display device 100 may include a display area DA and a non-display area NDA. The display device 100 may display an image through the display area DA. The non-display area NDA may be arranged around the display area DA.

The display device 100 may include a substrate SUB, sub-pixels SP, and pads PD.

When the display device 100 is used as a display screen of a head-mounted display (HMD) device, a virtual reality (VR) device, a mixed reality (MR) device, an augmented reality (AR) device, and/or the like, the display device 100 may be positioned very close to a user's eyes. In such cases, sub-pixels SP with relatively high integration may be desired or required.

In order to increase the integration of the sub-pixels SP, the substrate SUB may be provided as a silicon substrate. The sub-pixels SP may be formed on the substrate SUB, which is a silicon substrate. The display device 100 including a plurality of layers formed on the substrate SUB, which is a silicon substrate, may be referred to as an OLED on Silicon (OLEDoS) display device.

The sub-pixels SP may be arranged in the display area DA on the substrate SUB. The sub-pixels SP may be arranged in a matrix form along a first direction DR1 and a second direction DR2 intersecting the first direction DR1. However, the present disclosure is not limited thereto. For example, the sub-pixels SP may be arranged in a zigzag shape along the first direction DR1 and the second direction DR2. For example, the sub-pixels SP may be arranged in a PENTILE© shape (PENTILE© is a duly registered trademark of Samsung Display Co.). The first direction DR1 may be a row direction, and the second direction DR2 may be a column direction.

A plane (e.g., a plan view) defined in this specification may be a direction extending in the first direction DR1 and the second direction DR2 and may be defined based on a plane on which the substrate SUB is arranged. According to one or more embodiments, a third direction DR3 may be a thickness direction of the substrate SUB, and the third direction DR3 may be a direction in which light is emitted from the display device 100.

The sub-pixels SP may have one or more suitable shapes in a plan view, and the shapes of the sub-pixels SP are not limited to specific examples.

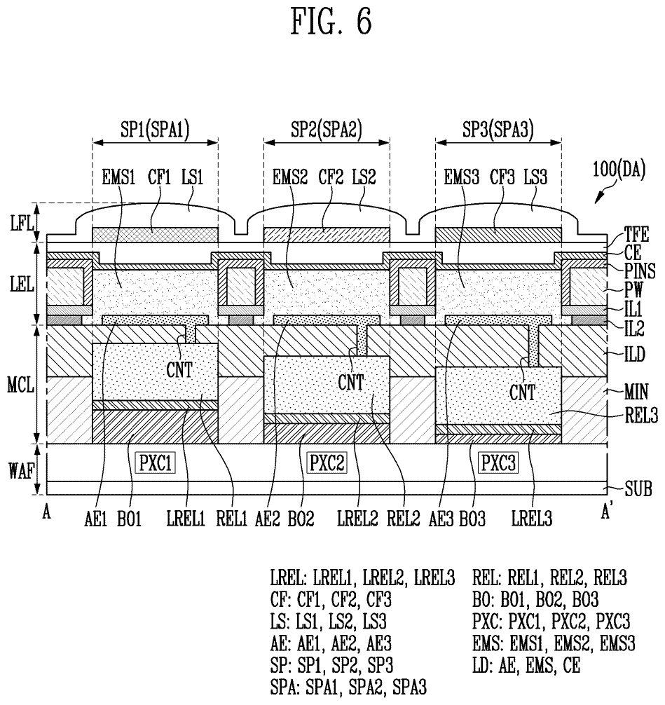

Each of the sub-pixels SP may include at least one light emitting element LD (see, e.g., FIG. 6) configured to generate light. Accordingly, each of the sub-pixels SP may generate light of a specific color, such as red, green, blue, cyan, magenta, or yellow. Among the sub-pixels SP, two or more sub-pixels SP may constitute a pixel PXL. For example, as shown in FIG. 1, three sub-pixels SP may constitute a pixel PXL.

Hereinafter, one or more embodiments in which the sub-pixels SP include a first sub-pixel SP1 providing light of a first color (for example, red), a second sub-pixel SP2 providing light of a second color (for example, green), and a third sub-pixel SP3 providing light of a third color (for example, blue) will be described as an example.

According to one or more embodiments, the first sub-pixel SP1 may be a red pixel and may provide light in a wavelength range of 600 nm to 750 nm. The second sub-pixel SP2 may be a green pixel and may provide light in a wavelength range of 480 nm to 560 nm. The third sub-pixel SP3 may be a blue pixel and may provide light in a wavelength range of 370 nm to 460 nm.

Components for controlling the sub-pixels SP may be arranged in the non-display area NDA on the substrate SUB. For example, wirings (for example, gate lines, data lines, and/or the like for driving the sub-pixels SP) connected to the sub-pixels SP may be arranged in the non-display area NDA. In addition, a gate driver, a data driver, a voltage generator, a controller, a temperature sensor, and/or the like for acquiring driving signals supplied to the sub-pixels SP may be integrated in the non-display area NDA of the display device 100. However, the present disclosure is not limited thereto.

The pads PD may be arranged in the non-display area NDA on the substrate SUB. The pads PD may be electrically connected to the sub-pixels SP through the wirings. For example, the pads PD may be connected to the sub-pixels SP through the data lines.

The pads PD may interface components within the display area DA and the non-display area NDA with other components of the display device 100. In one or more embodiments, voltages and signals necessary for the operation of components included in the display device 100 may be provided from a driver integrated circuit through the pads PD. For example, the data lines may be electrically connected to the driver integrated circuit through the pads PD. For example, power source voltages for driving the sub-pixels SP may be received from the driver integrated circuit through the pads PD. For example, a gate control signal for controlling the gate driver may be transmitted from the driver integrated circuit to the gate driver through the pads PD.

In one or more embodiments, a circuit board may be electrically connected to the pads PD using a conductive adhesive member such as an anisotropic conductive film. In this case, the circuit board may be a flexible circuit board or a flexible film made of a flexible material. The driver integrated circuit may be mounted on the circuit board and electrically connected to the pads PD.

In one or more embodiments, the display area DA may have one or more suitable shapes. The display area DA may have a closed loop shape including straight and/or curved sides. For example, the display area DA may have shapes such as a polygon, circle, semicircle, or ellipse.

In one or more embodiments, the display device 100 may have a flat display surface. In one or more embodiments, the display device 100 may have a display surface that is at least partially round. In one or more embodiments, the display device 100 may be bent, folded, or rolled. In these cases, the display device 100, specifically, the substrate SUB included in the display device 100, may include materials with flexible properties.

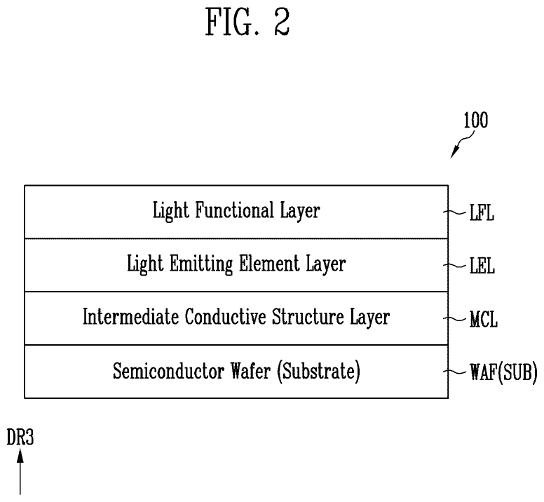

FIG. 2 is a cross-sectional view schematically illustrating the display device according to one or more embodiments of the present disclosure.

Referring to FIG. 2, the display device 100 according to one or more embodiments may include a semiconductor wafer WAF, an intermediate conductive structure layer MCL, a light emitting element layer LEL, and a light functional layer LFL.

The semiconductor wafer WAF may include a substrate SUB. The substrate SUB may form a base on which other components of the display device 100 are arranged. The substrate SUB may include a silicon substrate.

According to one or more embodiments, the semiconductor wafer WAF may be a CMOS (Complementary Metal Oxide Semiconductor) wafer and may include a pixel circuit PXC (see, e.g., FIG. 6) for driving the sub-pixel SP.

The intermediate conductive structure layer MCL may be arranged on the substrate SUB. A portion of the intermediate conductive structural layer MCL may couple the substrate SUB and the intermediate conductive structural layer MCL. The intermediate conductive structure layer MCL may form resonance paths based on different resonance distances for each of the sub-pixels SP, thereby improving the light emitting efficiency of the sub-pixels SP.

The light emitting element layer LEL may be a layer including the light emitting element LD that provides light. Light provided by the light emitting element LD may be output to the outside along the third direction DR3.

The light functional layer LFL may be arranged on the light emitting element layer LEL. The light functional layer LFL may include one or more suitable functional layers to more clearly implement a full-color display structure and improve light output efficiency. For example, the light functional layer LFL may include color filters CF (see, e.g., FIG. 6) and may also include lenses LS.

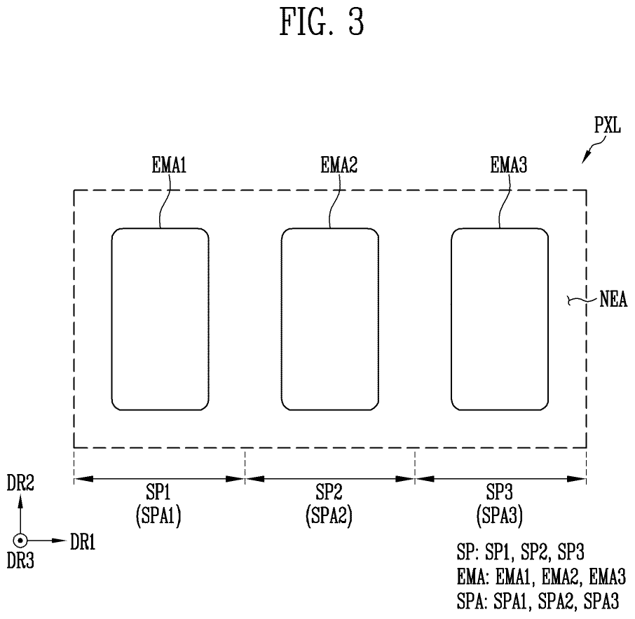

FIG. 3 is a plan view schematically illustrating a pixel according to one or more embodiments of the present disclosure.

Referring to FIG. 3, the pixel PXL may include sub-pixels SP arranged in the first direction DR1. For example, the sub-pixels SP may include a first sub-pixel SP1, a second sub-pixel SP2, and a third sub-pixel SP3 arranged in the first direction DR1. Emission areas EMA may include first to third emission areas EMA1 to EMA3.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

The sub-pixels SP may include sub-pixel areas SPA where light of a color is visually recognized. The sub-pixel areas SPA may include a first sub-pixel area SPA1 where the first sub-pixel SP1 is formed and light of the first color is visually recognized, a second sub-pixel area SPA2 where the second sub-pixel SP2 is formed and light of the second color is visually recognized, and a third sub-pixel area SPA3 where the third sub-pixel SP3 is formed and light of the third color is visually recognized.

The first emission area EMA1 may be an area where light is emitted from a portion of an emission structure EMS (for example, a first emission structure EMS1) (see, e.g., FIG. 6) corresponding to the first sub-pixel SP1. The second emission area EMA2 may be an area where light is emitted from a portion of the emission structure EMS (for example, a second emission structure EMS2) corresponding to the second sub-pixel SP2. The third emission area EMA3 may be an area where light is emitted from a portion of the emission structure EMS (for example, a third emission structure EMS3) corresponding to the third sub-pixel SP3.

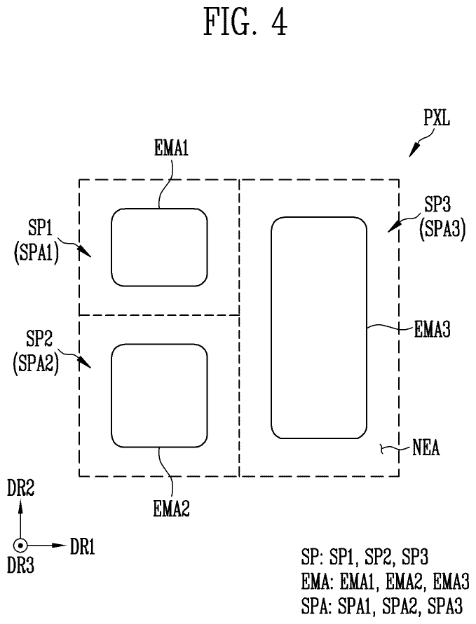

FIG. 4 is a plan view schematically illustrating a pixel according to one or more embodiments of the present disclosure.

Referring to FIG. 4, a first sub-pixel SP1 and a second sub-pixel SP2 may be arranged in the second direction DR2. A third sub-pixel SP3 may be arranged in the first direction DR1 with respect to each of the first and second sub-pixels SP1 and SP2.

The second sub-pixel SP2 may have a larger area than the first sub-pixel SP1, and the third sub-pixel SP3 may have a larger area than the second sub-pixel SP2. Accordingly, a second emission area EMA2 may have a larger area than a first emission area EMA1, and a third emission area EMA3 may have a larger area than the second emission area EMA2. However, the present disclosure is not limited thereto. For example, the first and second sub-pixels SP1 and SP2 may have substantially the same area, and the third sub-pixel SP3 may have a larger area than each of the first and second sub-pixels SP1 and SP2. As such, areas of the first to third sub-pixels SP1 to SP3 may vary depending on the embodiment.

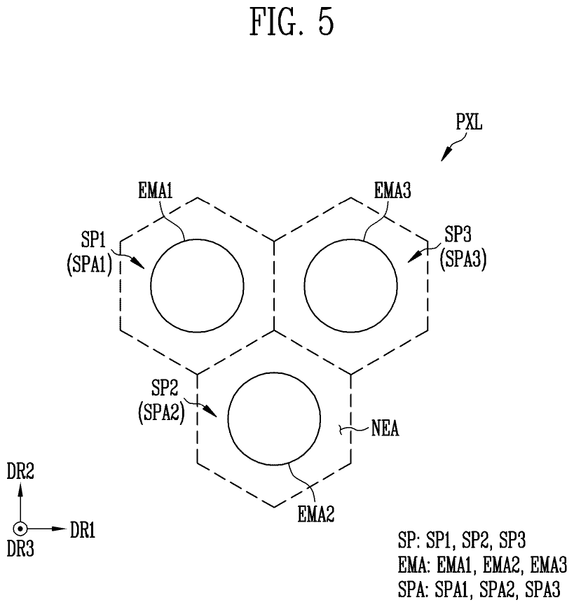

FIG. 5 is a plan view schematically illustrating a pixel according to still one or more embodiments of the present disclosure.

Referring to FIG. 5, first to third sub-pixels SP1 to SP3 may have a polygonal shape when viewed from the third direction DR3 (e.g., in a plan view). For example, the first to third sub-pixels SP1 to SP3 may have a hexagonal shape as shown in FIG. 5.

First to third emission areas EMA1 to EMA3 may have a circular shape when viewed from the third direction DR3 (e.g., in a plan view). However, the present disclosure is not limited thereto. For example, each of the first to third emission areas EMA1 to EMA3 may have a polygonal shape.

The first and third sub-pixels SP1 and SP3 may be arranged in the first direction DR1. The second sub-pixel SP2 may be arranged in a direction inclined at an acute angle (or diagonally) relative to the second direction DR2 with respect to the first sub-pixel SP1.

The arrangements of the sub-pixels SP shown in FIGS. 3 to 5 are only examples, and the present disclosure is not limited thereto. Each pixel PXL may include two or more sub-pixels SP, and the sub-pixels SP may be arranged in one or more suitable ways. In addition, the sub-pixels SP may have one or more suitable shapes, and their emission areas EMA may also have one or more suitable shapes.

A display device 100 including an intermediate conductive structure layer MCL and/or the like according to one or more embodiments of the present disclosure will be described with reference to FIGS. 6 to 8. Content that may overlap with the above-described content may be briefly explained or omitted.

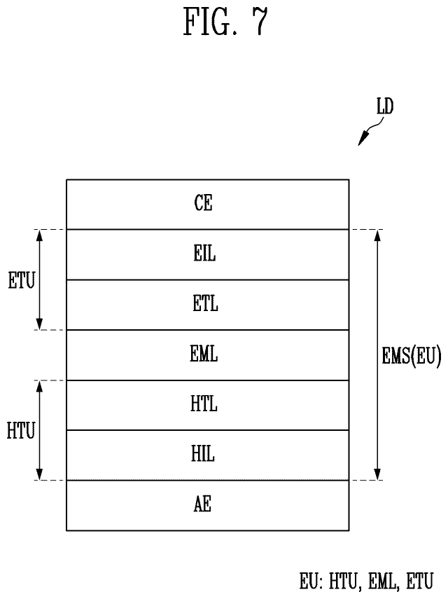

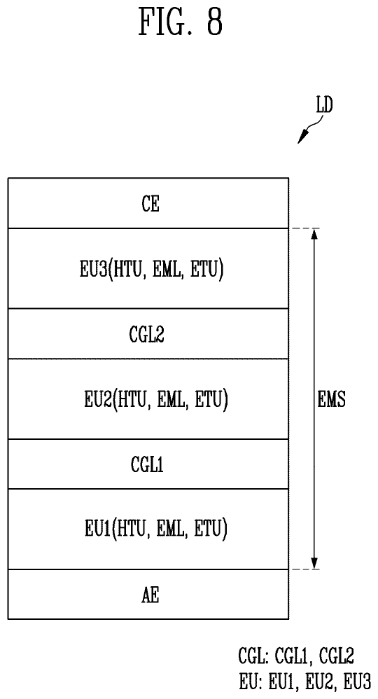

FIG. 6 is a cross-sectional view schematically illustrating a display device according to one or more embodiments of the present disclosure. FIG. 6 is a schematic cross-sectional view taken along the line A-A′ in FIG. 1, according to one or more embodiments of the present disclosure. FIG. 6 schematically shows a cross-sectional structure of the display device 100 within the display area DA. FIGS. 7 and 8 are each a cross-sectional view schematically illustrating a light emitting element according to one or more embodiments of the present disclosure.

Referring to FIGS. 6 to 8, the sub-pixels SP forming the sub-pixel areas SPA within the display area DA may be arranged (for example, formed) on the semiconductor wafer WAF (or substrate SUB).

According to one or more embodiments, the semiconductor wafer WAF may be a CMOS wafer and may include the pixel circuit PXC. The pixel circuit PXC may include a first pixel circuit PXC1 configured to drive the first sub-pixel SP1 and electrically connected to the light emitting element LD in the first sub-pixel area SPA1, a second pixel circuit PXC2 configured to drive the second sub-pixel SP2 and electrically connected to the light emitting element LD in the second sub-pixel area SPA2, and a third pixel circuit PXC3 configured to drive the third sub-pixel SP3 and electrically connected to the light emitting element LD in the third sub-pixel area SPA3.

The intermediate conductive structure layer MCL may be arranged on the semiconductor wafer WAF (or substrate SUB). According to one or more embodiments, the intermediate conductive structural layer MCL may include a bonding conductive layer BO, a lower conductive layer LREL, a reflective conductive layer REL, an intermediate insulating layer MIN, and an interlayer insulating layer ILD.

The bonding conductive layer BO may be arranged on the semiconductor wafer WAF (or substrate SUB). The bonding conductive layer BO may be arranged directly on the semiconductor wafer WAF. For example, the bonding conductive layer BO may be in contact with the top surface of the semiconductor wafer WAF.

The bonding conductive layer BO may include a first bonding conductive layer BO1 included in the first sub-pixel SP1, a second bonding conductive layer BO2 included in the second sub-pixel SP2, and a third bonding conductive layer BO3 included in the third sub-pixel SP3. The first to third bonding conductive layers BO1 to BO3 may be spaced and/or apart (e.g., spaced apart or separated) from each other.

The bonding conductive layer BO may couple (for example, bond) the intermediate conductive structure layer MCL to the semiconductor wafer WAF. The bonding conductive layer BO may be electrically connected to the pixel circuit PXC. For example, the first to third bonding conductive layers BO1 to BO3 may be electrically connected to the first to third pixel circuits PXC1 to PXC3.

The bonding conductive layer BO may be coupled to a conductive pad portion electrically connected to the pixel circuit PXC of the semiconductor wafer WAF. As an example, the semiconductor wafer WAF may include a conductive pad portion electrically connected to the pixel circuit PXC at the top surface, and the bonding conductive layer BO may be bonded to the conductive pad portion. Accordingly, the bonding conductive layer BO may be electrically connected to the pixel circuit PXC while coupling the semiconductor wafer WAF and the intermediate conductive structure layer MCL.

According to one or more embodiments, a via layer may not be interposed between the bonding conductive layer BO and the semiconductor wafer WAF. For example, the bonding conductive layer BO is not electrically connected to the semiconductor wafer WAF through a via hole penetrating the via layer, but the bonding conductive layer BO may form an electrical contact surface with a portion of the semiconductor wafer WAF and may be electrically connected to the pixel circuit PXC. Accordingly, the risk of excessive increase in resistance due to structures such as via holes and/or the like can be reduced. In addition, because an electrical path is formed based on the bonding conductive layer BO, resistance in the electrical path between the pixel circuit PXC and the light emitting element LD can be reduced. Accordingly, the risk of distortion of an electrical signal for the light emitting element LD to emit light can be reduced, and the reliability of the electrical signal can be improved. In other words, in some embodiments, there may be no via layer between the bonding conductive layer BO and the semiconductor wafer WAF. Instead of being connected through a via hole, the bonding conductive layer BO directly contacts a part of the semiconductor wafer WAF and connects to the pixel circuit PXC. This design reduces the risk of increased resistance from via holes and similar structures. Additionally, because the electrical path is formed by the bonding conductive layer BO, the resistance between the pixel circuit PXC and the light-emitting element LD is minimized or reduced. This helps reduce signal distortion for the light-emitting element LD and improves the reliability of the electrical signal.

The bonding conductive layer BO may be coupled to the semiconductor wafer WAF in one or more suitable ways. For example, the bonding conductive layer BO may be coupled to the semiconductor wafer WAF based on a solder bonding process and/or the like. The bonding conductive layer BO may be coupled to the semiconductor wafer WAF by Cu—Cu hybrid bonding. According to one or more embodiments, the bonding conductive layer BO may be coupled to the semiconductor wafer WAF based on a melt bonding process and/or the like. However, the present disclosure is not limited thereto.

The bonding conductive layer BO may be patterned through the same (or substantially the same) process and may include the same (or substantially the same) conductive material. According to one or more embodiments, the bonding conductive layer BO may include a conductive material through which a bonding process can be suitably performed. For example, the bonding conductive layer BO may include copper (Cu). However, the present disclosure is not limited thereto.

The bonding conductive layer BO may have different thicknesses (e.g., the thickness of the bonding conductive layer may vary throughout the bonding conductive layer BO). For example, at least some of the first to third bonding conductive layers BO1 to BO3 may have different thicknesses. For example, the first to third bonding conductive layers BO1 to BO3 may have different thicknesses. According to one or more embodiments, the thickness of the first bonding conductive layer BO1 may be greater than the thickness of the second bonding conductive layer BO2, and the thickness of the second bonding conductive layer BO2 may be greater than the thickness of the third bonding conductive layer BO3. In this specification, the thickness may be defined based on the third direction DR3 which is a thickness direction of the substrate SUB.

In such embodiments, different resonance distances may be defined in each of the sub-pixels SP. Because the resonance distance can be appropriately or suitably defined for each sub-pixel SP, the light output efficiency of the light emitting elements LD can be improved.

The lower conductive layer LREL may be arranged on the bonding conductive layer BO. The lower conductive layer LREL may be electrically connected to the bonding conductive layer BO.

The lower conductive layer LREL may include a first lower conductive layer LREL1 included in the first sub-pixel SP1, a second lower conductive layer LREL2 included in the second sub-pixel SP2, and a third lower conductive layer LREL3 included in the third sub-pixel SP3. The first to third lower conductive layers LREL1 to LREL3 may be spaced and/or apart (e.g., spaced apart or separated) from each other.

According to one or more embodiments, the first to third lower conductive layers LREL1 to LREL3 may have the same (or substantially the same) thickness. According to one or more embodiments, the first to third lower conductive layers LREL1 to LREL3 may be patterned within the same (or substantially the same) process and may include the same (or substantially the same) conductive material. For example, the first to third lower conductive layers LREL1 to LREL3 may include titanium (Ti), titanium nitride (TiN), tantalum (Ta), copper (Cu), a copper-manganese alloy, and/or the like. However, the present disclosure is not limited thereto.

The reflective conductive layer REL may be arranged on the lower conductive layer LREL. The reflective conductive layer REL may be electrically connected to the lower conductive layer LREL.

The reflective conductive layer REL may include a first reflective conductive layer REL1 included in the first sub-pixel SP1, a second reflective conductive layer REL2 included in the second sub-pixel SP2, and a third reflective conductive layer REL3 included in the third sub-pixel SP3, and the first reflective conductive layer REL1, the second reflective conductive layer REL2 and the third reflective conductive layer REL3 may have the same (or substantially the same) thickness.

The reflective conductive layer REL may function as a full mirror that reflects light emitted from the emission structure EMS toward the display screen. At least a portion of the reflective conductive layer REL may include metal materials suitable for reflecting light. For example, the metal materials may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected from among them.

The intermediate insulating layer MIN may be arranged on the semiconductor wafer WAF (or substrate SUB) and may be arranged on side surfaces of the bonding conductive layer BO, the lower conductive layer LREL, and the reflective conductive layer REL. The intermediate insulating layer MIN may be arranged on the semiconductor wafer WAF (or substrate SUB) in areas where the bonding conductive layer BO, the lower conductive layer LREL, and the reflective conductive layer REL are not arranged.

The lower surface of the intermediate insulating layer MIN may be arranged in the same plane as the lower surface of the bonding conductive layer BO. For example, the lower surface of the intermediate insulating layer MIN and the lower surface of the bonding conductive layer BO may be provided by the same (or substantially the same) planarization process (for example, a chemical mechanical polishing (CMP) process).

The intermediate insulating layer MIN may include an inorganic material. According to one or more embodiments, the intermediate insulating layer MIN may include one or more of silicon nitride (SiₓN_{y}, where the range for x may be from 0 to 3, and the range for y may be from 0 to 4, e.g., Si₃N₄), silicon oxide (SiOₓ, where 0<x≤2, e.g., SiO₂), silicon oxynitride (SiOxNy, where the range for x may be from 0 to 2, and the range for y may be from 0 to 4), and aluminum oxide (AlₓO_{y}, e.g., the range for x may be from 0 to 2, and the range for y may be from 0 to 3). However, the present disclosure is not limited thereto.

The interlayer insulating layer ILD may be arranged on the reflective conductive layer REL and the intermediate insulating layer MIN. The interlayer insulating layer ILD may be arranged across the first to third sub-pixel areas SPA1 to SPA3. The interlayer insulating layer ILD may cover at least a portion of the reflective conductive layer REL. The interlayer insulating layer ILD may be arranged between the reflective conductive layer REL and the light emitting element LD.

The interlayer insulating layer ILD may be a structure for forming a resonance structure. For example, in each of the sub-pixel areas SPA, the distance between an upper surface of the reflective conductive layer REL and a cathode electrode CE may be understood as a resonance distance of each sub-pixel SP. The interlayer insulating layer ILD may have different thicknesses for each sub-pixel SP under the emission structures EMS. According to one or more embodiments, the interlayer insulating layer ILD may have different thicknesses in each of the sub-pixel areas SPA. Accordingly, different resonance distances may be defined for each sub-pixel SP. The resonance distance adjusted in this way can allow light in a specific wavelength range to be amplified effectively and efficiently.

According to one or more embodiments, the thickness of the interlayer insulating layer ILD in the first sub-pixel area SPA1 may be smaller than the thickness of the interlayer insulating layer ILD in the second sub-pixel area SPA2. The thickness of the interlayer insulating layer ILD in the second sub-pixel area SPA2 may be smaller than the thickness of the interlayer insulating layer ILD in the third sub-pixel area SPA3. However, the present disclosure is not limited thereto. The thickness relationship of the interlayer insulating layer ILD between the sub-pixel areas SPA may be appropriately or suitably changed.

The interlayer insulating layer ILD may include an inorganic material. For example, the interlayer insulating layer ILD may include one or more of silicon nitride (SiNₓ), silicon oxide (SiOₓ), silicon oxynitride (SiOₓN_{y}), and aluminum oxide (AlₓO_{y}). According to one or more embodiments, the interlayer insulating layer ILD may include an oxide, for example, silicon oxide (SiOₓ). However, the present disclosure is not limited thereto.

According to one or more embodiments, the interlayer insulating layer ILD and the intermediate insulating layer MIN may include the same (or substantially the same) material. For example, the interlayer insulating layer ILD and the intermediate insulating layer MIN may include silicon oxide (SiOₓ).

The light emitting element layer LEL may be arranged on the intermediate conductive structure layer MCL. The light emitting element layer LEL may include first and second insulating layers IL1 and IL2, a partition wall PW, a partition wall insulating layer PINS, an anode electrode AE, the emission structure EMS, the cathode electrode CE, and an encapsulation layer TFE.

The first and second insulating layers IL1 and IL2 may be arranged on the interlayer insulating layer ILD between the sub-pixel areas SPA. The first and second insulating layers IL1 and IL2 may be arranged below the partition wall PW.

The first and second insulating layers IL1 and IL2 may include an inorganic material. The first and second insulating layers IL1 and IL2 may include one or more of silicon nitride (SiNₓ), silicon oxide (SiOₓ), silicon oxynitride (SiOₓN_{y}), and aluminum oxide (AlₓO_{y}). However, the present disclosure is not limited to these specific examples.

According to one or more embodiments, the first and second insulating layers IL1 and IL2 may not overlap the bonding conductive layer BO, the lower conductive layer LREL, or the reflective conductive layer REL in a plan view, and may overlap the partition wall PW.

The first and second insulating layers IL1 and IL2 may include different materials and have different widths. For example, the first insulating layer IL1 may protrude (e.g., may protrude in a first direction DR1 and/or second direction DR2) relative to the second insulating layer IL2.

The partition wall PW may be arranged on the first and second insulating layers IL1 and IL2 between the sub-pixel areas SPA.

The partition wall PW may separate the sub-pixels SP. For example, the partition wall PW may be arranged between adjacent emission structures EMS. For example, each of the first to third emission structures EMS1 to EMS3 may be arranged between adjacent partition walls PW.

According to one or more embodiments, the partition wall PW may physically separate the sub-pixels SP. Accordingly, the risk of color mixing between the sub-pixels SP can be reduced. In other words, in some embodiments, the first and second insulating layers IL1 and IL2 do not overlap the bonding conductive layer BO, the lower conductive layer LREL, or the reflective conductive layer REL in a plan view, but they do overlap the partition wall PW. These insulating layers may be made of different materials and have different widths, with first insulating layer IL1 protruding more than the second insulating layer IL2. The partition wall PW is positioned on these insulating layers between sub-pixel areas SPA to separate the sub-pixels SP and protect the sub-pixels SP from color mixing, thereby improving display quality.

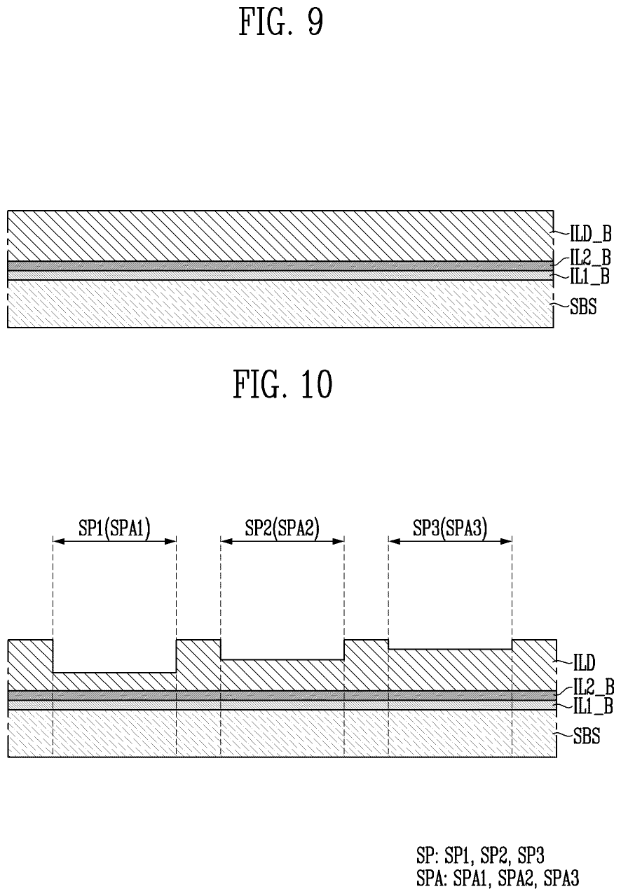

The partition wall PW may be manufactured based on a base SBS (see, e.g., FIG. 9) for manufacturing the intermediate conductive structural layer MCL. For example, the partition wall PW may include silicon (Si). However, the material of the partition wall PW is not limited thereto.

The partition wall insulating layer PINS may be arranged between the sub-pixel areas SPA. The partition wall insulating layer PINS may cover the side and upper surfaces of the partition wall PW. A portion of the partition wall insulating layer PINS may face the emission structure EMS, and another portion of the partition wall insulating layer PINS may face the cathode electrode CE.

The partition wall insulating layer PINS may include one or more suitable inorganic materials. For example, the partition wall insulating layer PINS may include one or more of silicon oxide (SiOₓ), silicon nitride (SiNₓ), titanium oxide (TiOₓ, where 0<x≤2, e.g., TiO₂), and/or aluminum oxide (AlₓO_{y}). However, the present disclosure is not limited thereto.

According to one or more embodiments, the partition wall insulating layer PINS may be formed on the partition wall PW arranged between the sub-pixel areas SPA. Accordingly, the risk of leakage current between adjacent sub-pixels SP can be further reduced. In other words, in some embodiments, the partition wall insulating layer PINS may be formed on the partition wall PW located between the sub-pixel areas SPA. This helps further reduce the risk of leakage current between adjacent sub-pixels SP.

According to one or more embodiments, the partition wall insulating layer PINS and the first insulating layer IL1 may include the same (or substantially the same) material. In such embodiments, an etching process for manufacturing the partition wall insulating layer PINS and the first insulating layer IL1 may be performed concurrently (e.g., simultaneously).

The anode electrode AE may be arranged on the interlayer insulating layer ILD in the sub-pixel area SPA. The anode electrode AE may overlap the reflective conductive layer REL in a plan view. The anode electrode AE may be arranged between adjacent partition walls PW.

The anode electrode AE may include a first anode electrode AE1 included in the first sub-pixel SP1, a second anode electrode AE2 included in the second sub-pixel SP2, and a third anode electrode AE3 included in the third sub-pixel SP3.

The anode electrode AE may include at least one of transparent conductive materials such as indium tin oxide (ITO), indium zinc oxide (IZO), zinc oxide (ZnOx), indium gallium zinc oxide (IGZO), and/or indium tin zinc oxide (ITZO). However, the material of the anode electrode AE is not limited thereto. For example, the anode electrode AE may include titanium nitride.

The anode electrode AE may be electrically connected to the reflective conductive layer REL through a contact portion CNT penetrating the interlayer insulating layer ILD. Accordingly, the anode electrode AE may receive an anode voltage from the pixel circuit PXC.

The emission structure EMS may be to emit light based on an electrical signal provided from the anode electrode AE and the cathode electrode CE. In each of the first to third sub-pixels SP1 to SP3, holes injected from the anode electrode AE and electrons injected from the cathode electrode CE may be transported into the light emitting layer EML of the emission structure EMS to form excitons, and light may be generated as the excitons transition from the excited state to the ground state. The luminance of the light may be determined depending on the amount of current flowing through the light emitting layer EML. Depending on the configuration of the light emitting layer EML, the wavelength range of the generated light can be determined.

A first surface of the emission structure EMS may be electrically connected to the anode electrode AE, and a second surface of the emission structure EMS may be electrically connected to the cathode electrode CE.

The emission structure EMS may include a first emission structure EMS1 forming the first sub-pixel SP1 and arranged in the first sub-pixel area SPA1, a second emission structure EMS2 forming the second sub-pixel SP2 and arranged in the second sub-pixel area SPA2, and a third emission structure EMS3 forming the third sub-pixel SP3 and arranged in the third sub-pixel area SPA3.

The emission structure EMS may be arranged between the partition walls PW. The emission structure EMS may be adjacent to the partition walls PW in a plane direction in which the substrate SUB is arranged (e.g., in a plane substantially parallel to the plane in which the substrate SUB is arranged).

The emission structure EMS may include a multi-layer structure electrically connected between the anode electrode AE and the cathode electrode CE.

The emission structure EMS may include a light emitting unit EU including a plurality of layers. As shown, for example, in FIG. 7, the light emitting unit EU may include a plurality of emission structures including a hole transport unit HTU, a light emitting layer (or light generating layer) EML, and an electron transport unit ETU. Each layer forming the emission structure may include one organic material, and according to one or more embodiments, may further include an inorganic material such as a metal-containing compound or quantum dots.

The hole transport unit HTU may include a multi-layer structure having a plurality of layers each including different materials. As an example, the hole transport unit HTU may include a hole injection layer HIL and a hole transport layer HTL, and according to one or more embodiments, may further include a light emitting auxiliary layer, an electron blocking layer, and/or the like.

The light emitting layer EML may include a material capable of emitting light of a color. The light emitting layer EML may include a host and a dopant. The host of the light emitting layer EML may be a light emitting material that can capture carriers (electrons and holes) for generating light, and may induce the efficient generation of excitons. The dopant may include a phosphorescent dopant or a fluorescent dopant. According to one or more embodiments, examples of the dopant are not particularly limited. According to one or more embodiments, the dopant may include one organic material or may include a metal complex and/or the like.

The electron transport unit ETU may include a multi-layer structure having a plurality of layers each including different materials. The electron transport unit ETU may include an electron injection layer EIL and an electron transport layer ETL, and according to one or more embodiments, may further include an electron buffer layer, a hole blocking layer, and/or the like.

According to one or more embodiments (see, e.g., FIG. 7), the emission structure EMS may include a single light emitting unit EU. In such embodiments, the emission structure EMS may include different materials in each sub-pixel SP. For example, the emission structure EMS may include a first emission structure EMS1 arranged in the first sub-pixel SP1 and including a material for emitting light of the first color, a second emission structure EMS2 arranged in the second sub-pixel SP2 and including a material for emitting light of the second color, and a third emission structure EMS3 arranged in the third sub-pixel SP3 and including a material for emitting light of the third color.

According to one or more embodiments (see, e.g., FIG. 8), the emission structure EMS may have a tandem structure. For example, the emission structure EMS may include a plurality of light emitting units EU and a charge generation layer CGL arranged between the plurality of light emitting units EU. The charge generation layer CGL may be arranged between the light emitting units EU to guide the flow of current. In one or more embodiments, the charge generation layer CGL may have a stacked structure of a p dopant layer and an n dopant layer. According to one or more embodiments, the light emitting units EU may include a first light emitting unit EU1 providing light of the first color, a second light emitting unit EU2 providing light of the second color, and a third light emitting unit EU3 providing light of the third color. The charge generation layer CGL may include a first charge generation layer CGL1 and a second charge generation layer CGL2. According to one or more embodiments, in the emission structure EMS, the first light emitting unit EU1, the first charge generation layer CGL1, the second light emitting unit EU2, the second charge generation layer CGL2, and the third light emitting unit EU3 may be arranged sequentially.

The cathode electrode CE may be arranged on the emission structure EMS. The cathode electrode CE may be arranged across the first to third sub-pixel areas SPA1 to SPA3, and may be provided in common to the first to third sub-pixels SP1 to SP3. The cathode electrode CE may function as a half mirror that partially transmits and partially reflects light emitted from the emission structure EMS. However, the present disclosure is not limited thereto.

According to one or more embodiments, the cathode electrode CE may include at least one of silver (Ag), magnesium (Mg), and/or (e.g., any suitable) mixtures thereof. However, the material of the cathode electrode CE is not limited thereto. According to one or more embodiments, the cathode electrode CE may include at least one of transparent conductive materials such as indium tin oxide (ITO), indium zinc oxide (IZO), zinc oxide (ZnOx), indium gallium zinc oxide (IGZO), and/or indium tin zinc oxide (ITZO).

According to one or more embodiments, one of the first to third anode electrodes AE1 to AE3, one of the first to third emission structures EMS1 to EMS3, and a portion of the cathode electrode CE may be understood as constituting the light emitting element LD of each of the first to third sub-pixels SP1 to SP3.

As shown, for example, in FIG. 6, the encapsulation layer TFE may be arranged on the cathode electrode CE and may be arranged across the first to third sub-pixel areas SPA1 to SPA3. The encapsulation layer TFE may include a plurality of insulating films covering the light emitting element LD. According to one or more embodiments, the encapsulation layer TFE may include an inorganic layer and an organic layer. For example, the encapsulation layer TFE may have a structure in which a first inorganic layer/an organic layer/a second inorganic layer are sequentially arranged. However, the present disclosure is not limited thereto. According to one or more embodiments, the encapsulation layer TFE may be a thin film encapsulation film.

The light functional layer LFL may be arranged on the encapsulation layer TFE. The light functional layer LFL may include color filters CF and lenses LS.

The color filters CF may selectively transmit light of a color. For example, the color filters CF may include a first color filter CF1 arranged in the first sub-pixel area SPA1, a second color filter CF2 arranged in the second sub-pixel area SPA2, and a third color filter CF3 arranged in the third sub-pixel area SPA3.

The first color filter CF1 may include a dye and/or pigment that selectively transmits light of the first color. The second color filter CF2 may include a dye and/or pigment that selectively transmits light of the second color. The third color filter CF3 may include a dye and/or pigment that selectively transmits light of the third color.

The lenses LS may be arranged on the color filters CF. For example, the lenses LS may include a first lens LS1 overlapping the first sub-pixel area SPA1, a second lens LS2 overlapping the second sub-pixel area SPA2, and a third lens LS3 overlapping the third sub-pixel area SPA3.

The lenses LS may improve light output efficiency by outputting light emitted from the emission structure EMS through an intended path. The lenses LS may include an acrylic-based material. However, the material of the lenses LS is not limited thereto.

According to one or more embodiments, the display device 100 may further include additional layers in addition to the layers described above. For example, the display device 100 may further include a cover window and/or the like.

A method of manufacturing the display device 100 according to one or more embodiments will be described with reference to FIGS. 9 to 22. Content that may overlap with the above-described content (e.g., amount) may be briefly described or not repeated below.

FIGS. 9 to 22 are each a cross-sectional view schematically illustrating a process step (e.g., task or act) of a method of manufacturing a display device according to one or more embodiments of the present disclosure. For convenience of description, FIGS. 9 to 22 each show a cross-section based on the cross-sectional structure described above with reference to FIG. 6.

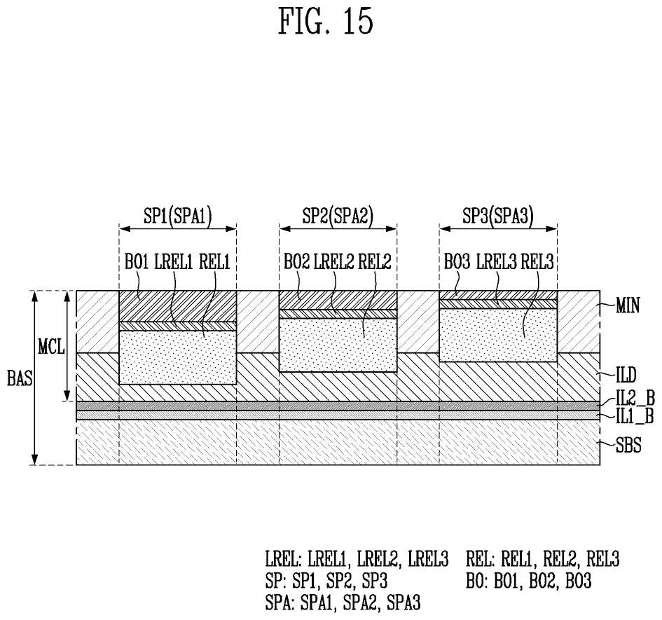

According to one or more embodiments, the display device 100 may be manufactured by providing a bonding assembly BAS (see, e.g., FIG. 15) including an intermediate conductive structural layer MCL, providing a semiconductor wafer WAF, coupling the bonding assembly BAS and the semiconductor wafer WAF, and disposing a light emitting element layer LEL and a light functional layer LFL on the bonding assembly BAS.

According to one or more embodiments, a first process in which the bonding assembly BAS is provided and a second process in which the semiconductor wafer WAF is manufactured may be performed separately. For example, the second process may be performed after the first process is performed, the first process may be performed after the second process is performed, or the first process and the second process may be performed in parallel and concurrently (e.g., simultaneously). Accordingly, process convenience can be improved and process steps can be simplified.

According to one or more embodiments, conductive layers or insulating layers on a base SBS and a substrate SUB may be formed based on common processes for manufacturing a semiconductor device. For example, conductive layers or insulating layers on the base SBS and the substrate SUB may be formed by photolithography processes, may be etched by one or more suitable methods (wet etching, dry etching, and/or the like), and may be deposited by one or more suitable methods (sputtering, chemical vapor deposition method, and/or the like). The present disclosure is not necessarily limited thereto.

First, a method of manufacturing the bonding assembly BAS including the intermediate conductive structural layer MCL will be described with reference to FIGS. 9 to 15.

Referring to FIG. 9, a first base insulating layer IL1_B, a second base insulating layer IL2_B, and a base interlayer insulating layer ILD_B may be formed on the base SBS.

According to one or more embodiments, the base SBS may be a substrate for manufacturing the intermediate conductive structure layer MCL. According to one or more embodiments, the base SBS may include a silicone material. The base SBS may be a substrate for manufacturing the intermediate conductive structural layer MCL, and a partition wall PW may be manufactured by patterning the base SBS in subsequent processes. Accordingly, additional processes can be reduced, and process costs can be reduced.

Referring to FIG. 10, at least portions of the base interlayer insulating layer ILD_B may be removed (for example, etched), and an interlayer insulating layer ILD may be manufactured.

In this step (e.g., act or task), the base interlayer insulating layer ILD_B may be patterned so that the interlayer insulating layer ILD has different thicknesses in sub-pixel areas SPA. Accordingly, the interlayer insulating layer ILD may have different thicknesses in the sub-pixel areas SPA to form resonance structures.

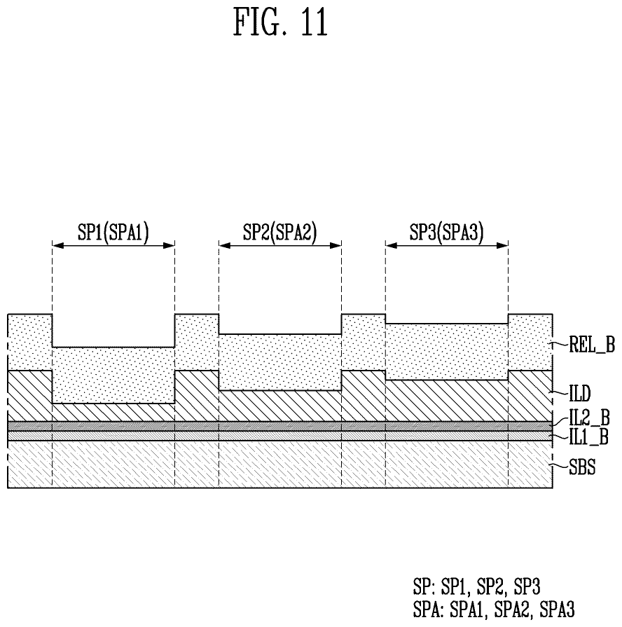

Referring to FIG. 11, a base reflective conductive layer REL_B may be formed (for example, deposited) on the interlayer insulating layer ILD.

In this step (e.g., act or task), the base reflective conductive layer REL_B may be formed across the sub-pixel areas SPA. The base reflective conductive layer REL_B may be formed to have a substantially uniform thickness across areas on the base SBS.

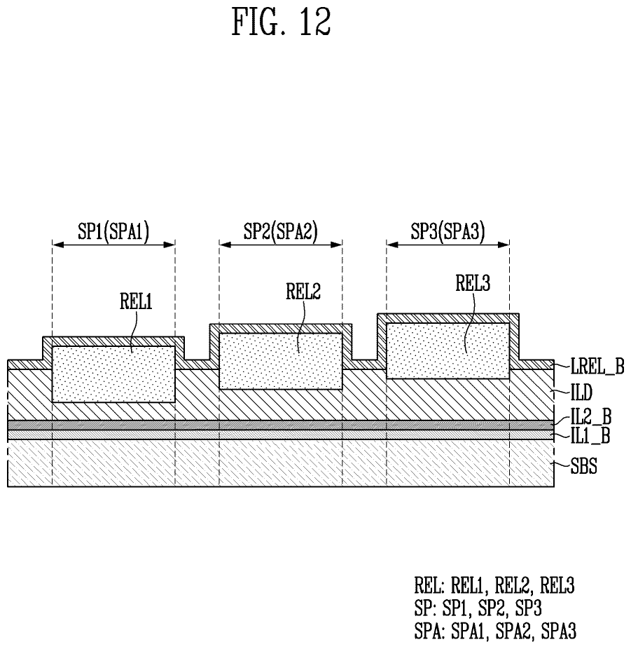

Referring to FIG. 12, at least portions of the base reflective conductive layer REL_B may be removed (for example, etched) to provide first to third reflective conductive layers REL1 to REL3. A base lower conductive layer LREL_B may be formed to cover the first to third reflective conductive layers REL1 to REL3 and portions of the interlayer insulating layer ILD.

In this step (e.g., act or task), the first to third reflective conductive layers REL1 to REL3 may be patterned to have a substantially uniform thickness.

According to one or more embodiments, in the display device 100, the first to third reflective conductive layers REL1 to REL3 formed below a resonance structure to form a light recycling structure may be patterned after the interlayer insulating layer ILD forming step differences for forming the resonance structure. In other words, the first to third reflective conductive layers REL1 to REL3 reflect light back toward the emission structures EMS through the interlayer insulating layer ILD, which is above the first to third reflective conductive layers REL1 to REL3. The first to third reflective conductive layers REL1 to REL3 may be patterned after the interlayer insulating layer ILD is formed. The interlayer insulating layer ILD has different thicknesses at different sub-pixels SP so that it forms a resonance structure for the light (e.g., specific color of light) of each sub-pixel, leading to constructive interference that improves light output.

According to one or more embodiments, the interlayer insulating layer ILD may include an oxide material. For example, because the interlayer insulating layer ILD including an oxide material is formed before the first to third reflective conductive layers REL1 to REL3 are formed, the risk of an oxide film being formed on the first to third reflective conductive layers REL1 to REL3 can be reduced. If an unintended structure, such as an oxide film, is formed in a part of a path through which an anode voltage is supplied, there may be a risk that anode voltage information is distorted. However, according to one or more embodiments, as described above, because the first to third reflective conductive layers REL1 to REL3 are patterned after the interlayer insulating layer ILD is formed, the above-described risk can be reduced. In other words, in some embodiments, the interlayer insulating layer ILD may include an oxide material. Forming this layer before the first to third reflective conductive layers REL1 to REL3 is formed helps reduce the risk of oxide films forming on these layers. This minimizes or reduces the chance of anode voltage distortion due to unintended structures like oxide films, as the reflective conductive layers REL are patterned after the interlayer insulating layer ILD is formed.

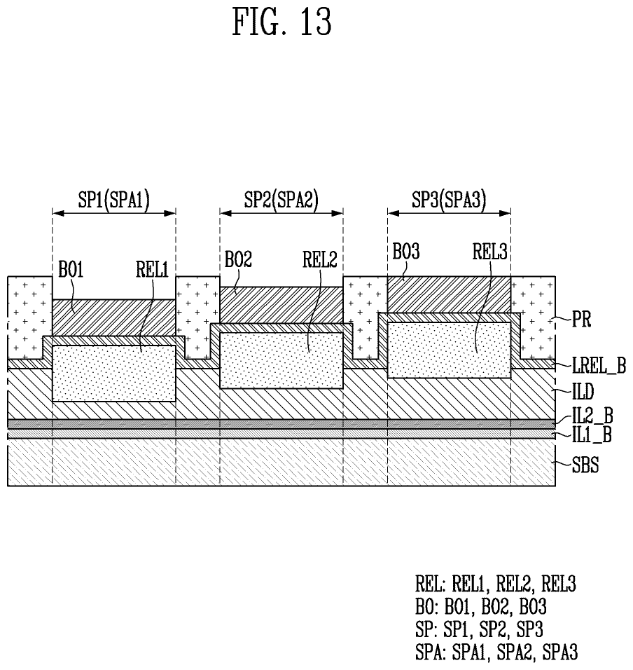

Referring to FIG. 13, a photoresist layer PR may be formed, and first to third bonding conductive layers BO1 to BO3 may be formed based on the photoresist layer PR.

In this step (e.g., act or task), the photoresist layer PR may be formed between the sub-pixel areas SPA. According to one or more embodiments, if (e.g., when) this step (e.g., act or task) is performed, the first to third bonding conductive layers BO1 to BO3 may have a substantially uniform thickness.

In this step (e.g., act or task), according to one or more embodiments, the first to third bonding conductive layers BO1 to BO3 may be formed based on an electro-plating method. However, the present disclosure is not limited thereto.

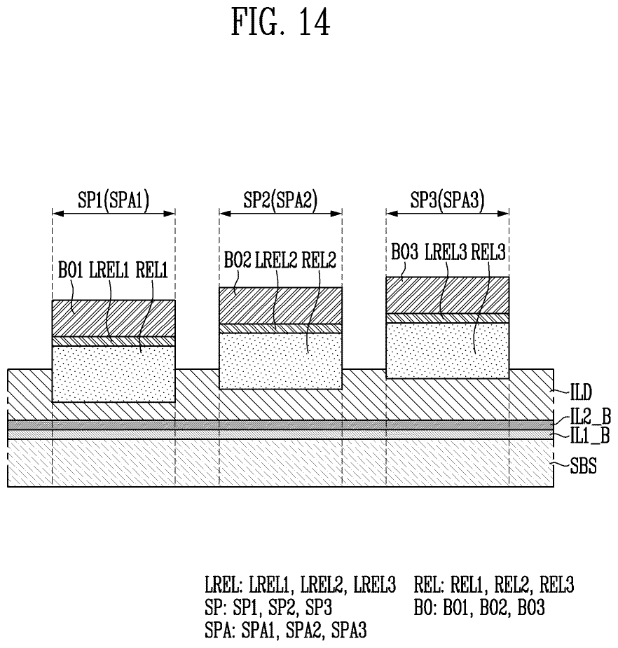

Referring to FIG. 14, the photoresist layer PR may be removed based on a strip process and/or the like, and at least portions of the base lower conductive layer LREL_B may be removed (for example, etched) to form first to third lower conductive layers LREL1 to LREL3.

Referring to FIG. 15, an intermediate insulating layer MIN may be arranged in areas between the sub-pixel areas SPA.

In this step (e.g., act or task), an insulating layer for planarization may be formed to fill the areas between the sub-pixel areas SPA, and the insulating layer for planarization and the first to third bonding conductive layers BO1 to BO3 may be planarized. The intermediate insulating layer MIN may be provided by removing at least a portion of the insulating layer for planarization. Accordingly, upper surfaces of the first to third bonding conductive layers BO1 to BO3 and the intermediate insulating layer MIN may form flat surfaces that substantially coincide with each other.

In this step (e.g., act or task), as the planarization process is performed, the first to third bonding conductive layers BO1 to BO3 may have different thicknesses. Accordingly, the bonding assembly BAS including the intermediate conductive structural layer MCL may be provided.

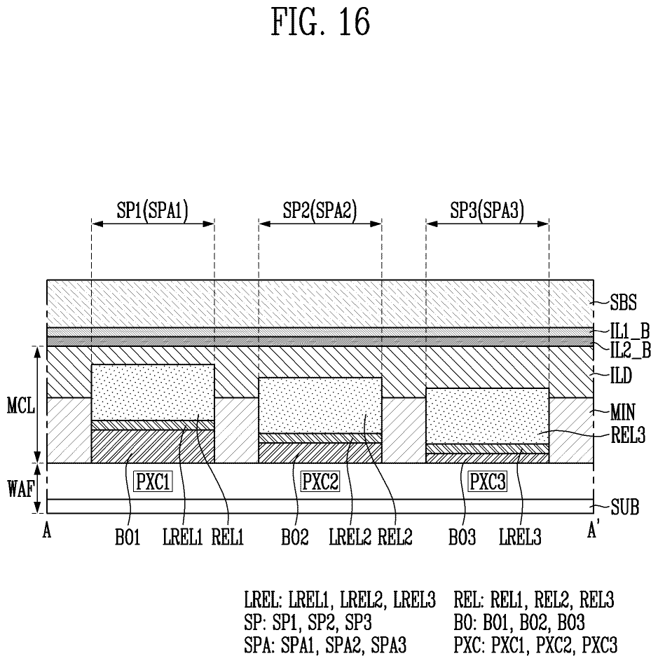

Referring to FIG. 16, which is vertically inverted relative to (compared to) FIG. 15, the semiconductor wafer WAF including the substrate SUB and a pixel circuit PXC may be provided, and the manufactured bonding assembly BAS (see, e.g., FIG. 15) may be arranged on the semiconductor wafer WAF.

In this step (e.g., act or task), the bonding assembly BAS may be arranged on the semiconductor wafer WAF so that the first to third bonding conductive layers BO1 to BO3 face the semiconductor wafer WAF. In this step (e.g., act or task), the semiconductor wafer WAF and the intermediate conductive structure layer MCL may be bonded using the first to third bonding conductive layers BO1 to BO3. According to one or more embodiments, as described above, the bonding conductive layer BO and the semiconductor wafer WAF may be coupled to each other by solder bonding or Cu—Cu hybrid bonding.

According to one or more embodiments, because upper surfaces of the first to third bonding conductive layers BO1 to BO3 and the intermediate insulating layer MIN form a substantially flat surface, the bonding assembly BAS may be appropriately or suitably arranged on the semiconductor wafer WAF. Accordingly, the first to third reflective conductive layers REL1 to REL3 and the interlayer insulating layer ILD to form the resonance structures may be formed on the semiconductor wafer WAF.

In this step (e.g., act or task), the first to third bonding conductive layers BO1 to BO3 may be electrically connected to the first to third pixel circuits PXC1 to PXC3.

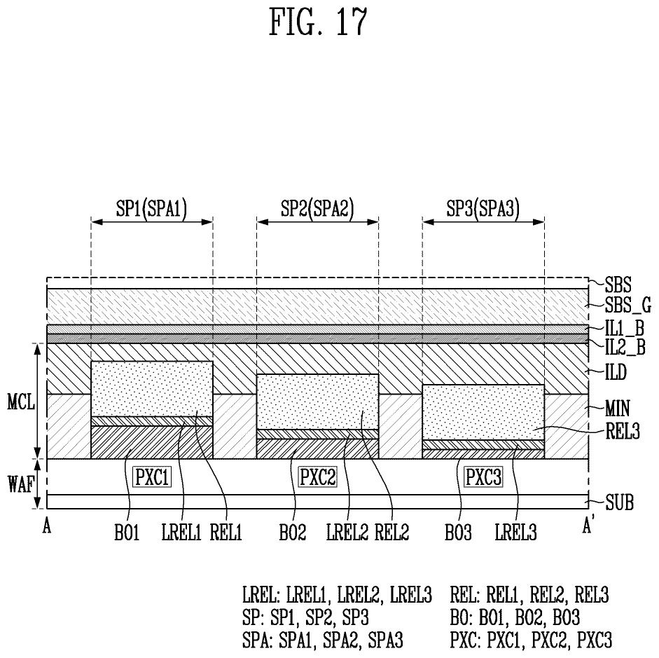

Referring to FIG. 17, at least a portion of the base SBS may be removed, and a partition wall base SBS_G with a reduced thickness may be provided.

In this step (e.g., act or task), at least a portion of the base SBS may be removed so that the base SBS has the thickness of the partition wall PW to be manufactured. Accordingly, a separate process for forming the partition wall PW may not be further performed, and the thickness of the partition wall PW may be appropriately or suitably defined.

In this step (e.g., act or task), a back grinding process for the base SBS may be performed. However, the present disclosure is not limited thereto. A polishing process and/or the like may be performed on the base SBS.

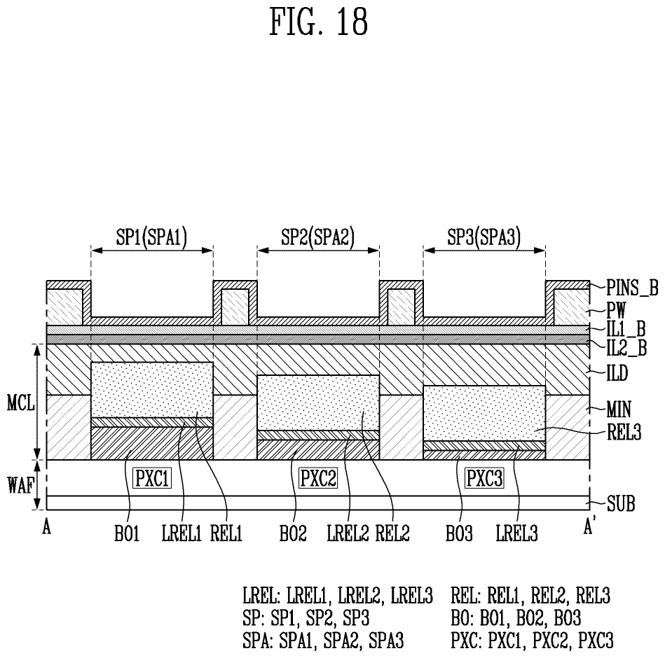

Referring to FIG. 18, by removing at least portions of the partition wall base SBS_G, the partition wall PW may be formed, and a partition wall base insulating layer PINS_B may be formed.

In this step (e.g., act or task), at least portions of the partition wall base SBS_G may be etched, and partition walls PW exposing the first base insulating layer IL1_B may be formed. Accordingly, the partition walls PW may be formed between the sub-pixel areas SPA.

In this step (e.g., act or task), the partition wall base insulating layer PINS_B may be deposited to cover the sub-pixel areas SPA, and the partition wall PW and the first base insulating layer IL1_B may be covered by the partition wall base insulating layer PINS_B.

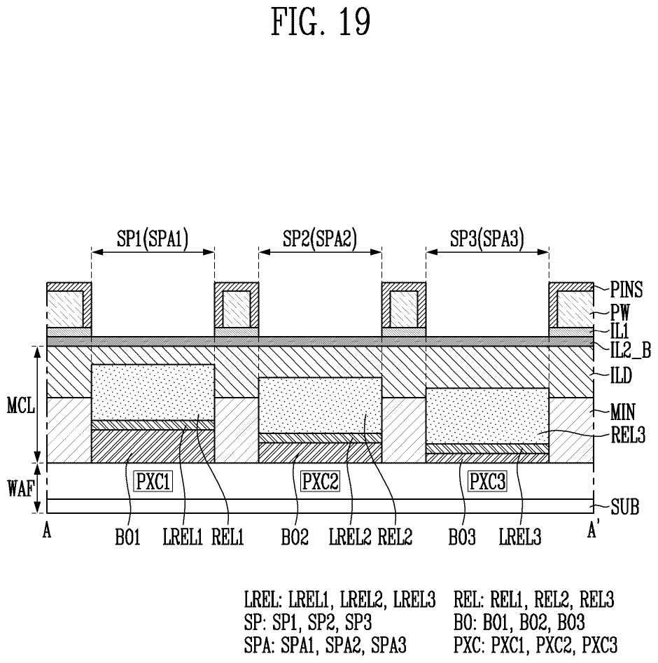

Referring to FIG. 19, at least portions of the partition wall base insulating layer PINS_B and the first base insulating layer IL1_B may be removed (for example, etched), and a first insulating layer IL1 and a partition wall insulating layer PINS that are not arranged in the sub-pixel areas SPA may be formed.

In this step (e.g., act or task), as at least portions of the partition wall base insulating layer PINS_B and the first base insulating layer IL1_B are removed, the second base insulating layer IL2_B may be exposed. According to one or more embodiments, the partition wall base insulating layer PINS_B and the first base insulating layer IL1_B may include the same (or substantially the same) material and may be etched concurrently (e.g., simultaneously).

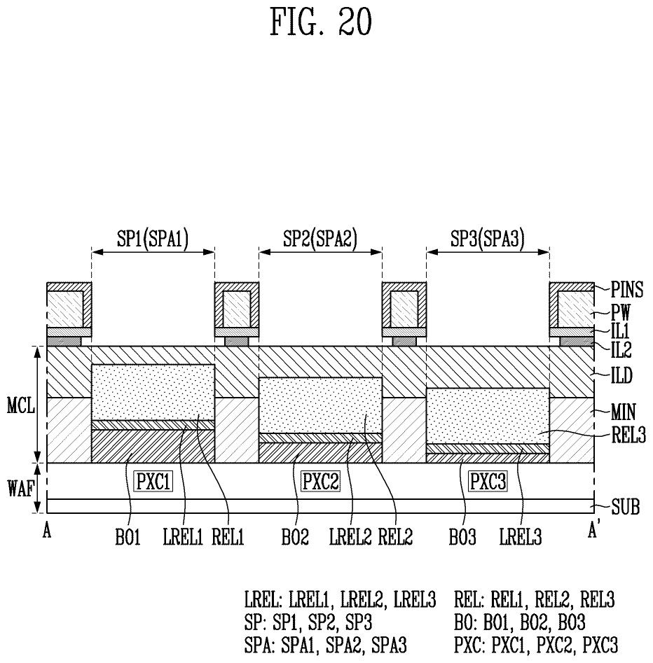

Referring to FIG. 20, at least a portion of the second base insulating layer IL2_B may be removed (for example, etched), and a second insulating layer IL2 may be formed.

In this step (e.g., act or task), the interlayer insulating layer ILD may be exposed as at least a portion of the second base insulating layer IL2_B is removed. According to one or more embodiments, the second base insulating layer IL2_B and the interlayer insulating layer ILD may include different (substantially different) materials, and an etching process for the second base insulating layer IL2_B may be performed until the interlayer insulating layer ILD is exposed.

According to one or more embodiments, the first and second insulating layers IL1 and IL2 may include different materials. Therefore, as the etching process is performed, the first and second insulating layers IL1 and IL2 may be patterned to have different widths.

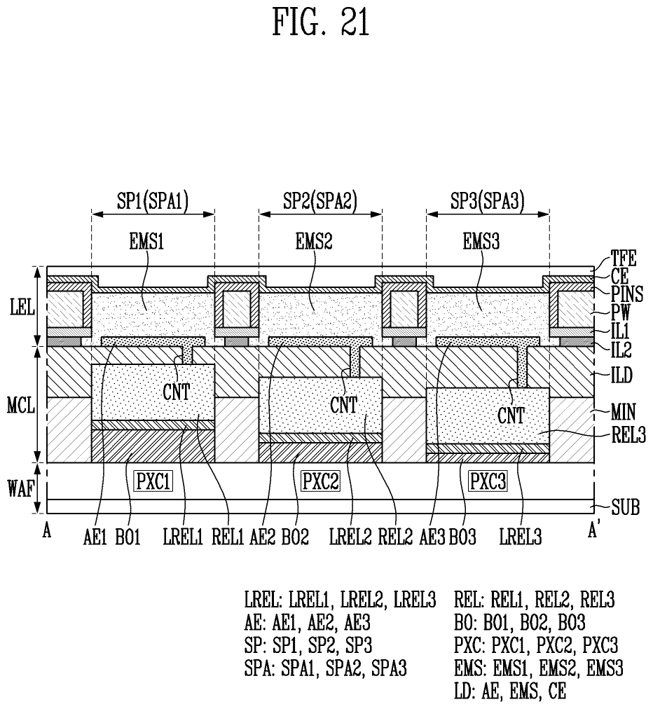

Referring to FIG. 21, an anode electrode AE may be formed on the interlayer insulating layer ILD, emission structures EMS may be disposed and/or arranged on the anode electrode AE, and a cathode electrode CE may be formed to cover the emission structures EMS. In addition, an encapsulation layer TFE may be formed on the cathode electrode CE.

In this step (e.g., act or task), a contact portion CNT that penetrates the interlayer insulating layer ILD and exposes a reflective conductive layer REL may be formed, and the anode electrode AE may be formed. Accordingly, first to third anode electrodes AE1 to AE3 may be electrically connected to the first to third reflective conductive layers REL1 to REL3 through contact portions CNT, respectively.

In this step (e.g., act or task), the emission structures EMS may be formed by one or more suitable methods. For example, the emission structures EMS may be disposed and/or arranged by one or more suitable processes such as deposition and coating. However, the present disclosure is not limited thereto.

In this step (e.g., act or task), the emission structures EMS may be disposed and/or arranged between the partition walls PW. According to one or more embodiments, the emission structures EMS for each sub-pixel SP may be separated by the partition wall PW. Accordingly, the risk of leakage current between adjacent sub-pixels SP can be reduced.

In this step (e.g., act or task), the cathode electrode CE may be disposed and/or arranged across the first to third sub-pixel areas SPA1 to SPA3. Accordingly, the cathode electrode CE may form a common electrode for the first to third sub-pixels SP1 to SP3.

In this step (e.g., act or task), the encapsulation layer TFE may be formed on the cathode electrode CE, and a plurality of layers forming the encapsulation layer TFE may be sequentially disposed and/or arranged.

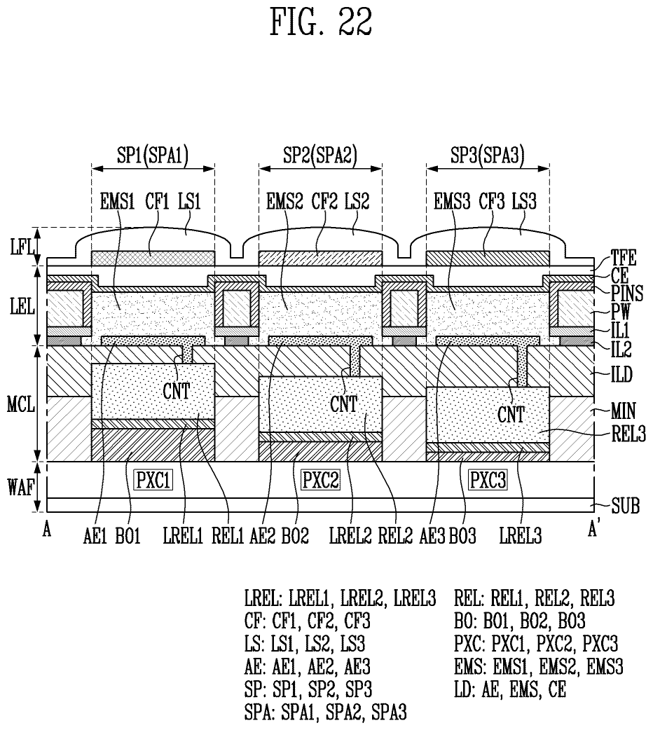

Referring to FIG. 22, a light functional layer LFL may be disposed and/or arranged on the encapsulation layer TFE.

In this step (e.g., act or task), first to third color filters CF1 to CF3 may be formed to overlap the first to third sub-pixel areas SPA1 to SPA3, and first to third lenses LS1 to LS3 may be formed to overlap the first to third sub-pixel areas SPA1 to SPA3.

Thereafter, according to one or more embodiments, additional components such as a cover window may be further formed on the lenses LS, and the display device 100 according to one or more embodiments may be provided.

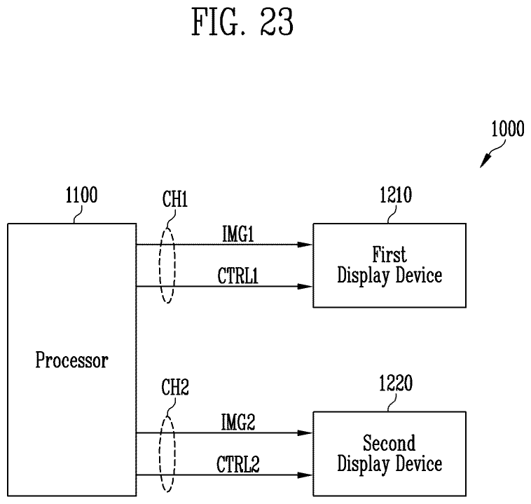

FIG. 23 is a block diagram illustrating an electronic device, according to one or more embodiments of the present disclosure.

Referring to FIG. 23, an electronic device 1000 may include a processor 1100 and one or more display devices 1210 and 1220. The electronic device 1000 may implement a display system.

The processor 1100 may perform one or more suitable tasks and calculations. In one or more embodiments, the processor 1100 may include an application processor, a graphics processor, a microprocessor, a central processing unit (CPU), and/or the like. The processor 1100 may be connected to and control other components of the electronic device 1000 through a bus system.

According to an embodiment, the processor 1100 may provide input image data to the display device 1210, 1220, and the display device 1210, 1220 may display images based on the input image data provided by the processor 1100.

In FIG. 23, the electronic device 1000 is shown as including first and second display devices 1210 and 1220. The processor 1100 may be connected to the first display device 1210 through a first channel CH1 and to the second display device 1220 through a second channel CH2.

Through the first channel CH1, the processor 1100 may be to transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1.

Through the second channel CH2, the processor 1100 may be to transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1.

The electronic device 1000 may include a computing system that provides an image (and/or video) display function, such as a portable computer, a mobile phone, a smart phone, a tablet personal computer, a smart watch, a watch phone, a portable multimedia player (PMP), a navigation, and/or an ultra-mobile personal computer (UMPC). In addition, the electronic device 1000 may include at least one of a head-mounted display (HMD) device, a virtual reality (VR) device, a mixed reality (MR) device, and/or an augmented reality (AR) device.

According to an embodiment, the electronic device 1000 may further include a memory device, a storage device, an input/output(I/O) device, a power supply.

The memory device may store data needed to perform the operation of the electronic device. For example, the memory device may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

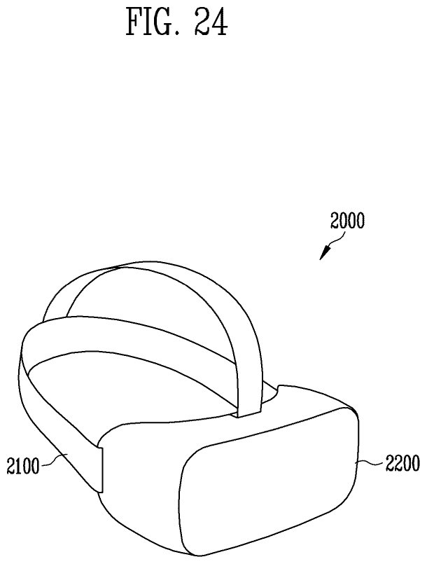

FIG. 24 is a perspective view illustrating a head-mounted display device as an example of an application of the electronic device of FIG. 23, according to one or more embodiments of the present disclosure.

Referring to FIG. 24, the electronic device 1000 of FIG. 23 may be applied to a head-mounted display device 2000. The head-mounted display device 2000 may be a wearable electronic device that can be worn on a user's head.

The head-mounted display device 2000 may include a head mounting band 2100 and a display device storage case 2200. The head mounting band 2100 may be connected to the display device storage case 2200. The head mounting band 2100 may include a horizontal band and/or a vertical band for fixing the head-mounted display device 2000 to the user's head. The horizontal band may be configured to be around (e.g., surround) the side of the user's head, and the vertical band may be configured to be around (e.g., surround) the top of the user's head. However, the present disclosure is not limited thereto. For example, the head mounting band 2100 may be implemented in the form of glasses frames, helmets, and/or the like.

The display device storage case 2200 may accommodate the first and second display devices 1210 and 1220 of FIG. 23. The display device storage case 2200 may further accommodate the processor 1100 of FIG. 23.

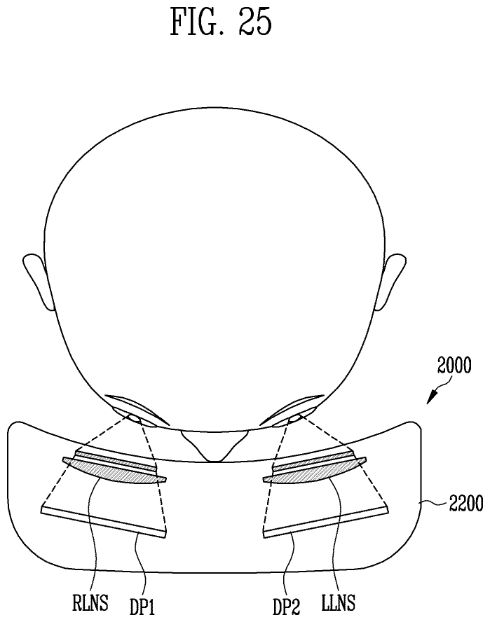

FIG. 25 is a diagram illustrating a head-mounted display device of FIG. 24 worn by a user, according to one or more embodiments of the present disclosure.

Referring to FIG. 25, within the head-mounted display device 2000, a first display panel DP1 of the first display device 1210 and a second display panel DP2 of the second display device 1220 may be arranged. The head-mounted display device 2000 may further include one or more lenses LLNS and RLNS.

Within the display device storage case 2200, a right eye lens RLNS may be arranged between the first display panel DP1 and the user's right eye. Within the display device storage case 2200, a left eye lens LLNS may be arranged between the second display panel DP2 and the user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function to adjust the viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function to adjust the viewing distance between the second display panel DP2 and the user's left eye.

In one or more embodiments, each of the right eye lens RLNS and the left eye lens LLNS may include an optical lens having a pancake-shaped (e.g., a convex-shaped) cross-section. In one or more embodiments, each of the right eye lens RLNS and the left eye lens LLNS may include a multi-channel lens including sub-regions with different optical properties. In such embodiments, each display panel may output images corresponding to the sub-regions of the multi-channel lens, and the output images may pass through corresponding sub-regions and may be displayed to the user.

According to aspects of one or more embodiments of the present disclosure, a display device in which the reliability of electrical signals provided to the display device can be improved and a method of manufacturing the same can be provided.

Aspects of embodiments of the present disclosure are directed to a display device in which risks in a manufacturing process can be reduced and a method of manufacturing the same.

Aspects of embodiments of the present disclosure are directed to a display device with excellent or suitable display quality and a method of manufacturing the same.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, a processing device, an electronic apparatus, a device or method for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a pixel comprising sub-pixel areas, the sub-pixel areas comprising a first sub-pixel area and a second sub-pixel area;
a semiconductor wafer comprising a substrate;
a bonding conductive layer on the semiconductor wafer;
a reflective conductive layer on the bonding conductive layer; and
a light emitting element electrically connected to the reflective conductive layer,
wherein the bonding conductive layer comprises a first bonding conductive layer in the first sub-pixel area and a second bonding conductive layer in the second sub-pixel area, and
wherein the first bonding conductive layer and the second bonding conductive layer have different thicknesses.

2. The display device of claim 1, further comprising:
an interlayer insulating layer covering the reflective conductive layer and between the reflective conductive layer and the light emitting element,
wherein the interlayer insulating layer has different thicknesses in the sub-pixel areas.

3. The display device of claim 2, further comprising:
a partition wall on the interlayer insulating layer between the sub-pixel areas.

4. The display device of claim 3, further comprising:
a partition wall insulating layer on the partition wall,
wherein the partition wall comprises silicon.

5. The display device of claim 4, wherein the bonding conductive layer comprises copper (Cu),
wherein the reflective conductive layer comprises at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected from among them, and
wherein the partition wall insulating layer comprises one or more of silicon oxide (SiOₓ), silicon nitride (SiNₓ), titanium oxide (TiOₓ), or aluminum oxide (AlₓO_{y}).

6. The display device of claim 4, further comprising:
a first insulating layer and a second insulating layer between the partition wall and the interlayer insulating layer and having different widths.

7. The display device of claim 1, wherein the semiconductor wafer comprises a pixel circuit on the substrate,
wherein the bonding conductive layer is electrically connected to the pixel circuit, and
wherein the bonding conductive layer and the semiconductor wafer are in direct contact with each other.

8. The display device of claim 1, wherein the bonding conductive layer and the semiconductor wafer are coupled to each other by solder bonding or Cu—Cu hybrid bonding.

9. The display device of claim 1, further comprising:
a lower conductive layer between the bonding conductive layer and the reflective conductive layer,
wherein the reflective conductive layer comprises a first reflective conductive layer in the first sub-pixel area and a second reflective conductive layer in the second sub-pixel area, and
wherein the first reflective conductive layer and the second reflective conductive layer have the same thickness.

10. The display device of claim 1, wherein the semiconductor wafer is a CMOS (Complementary Metal Oxide Semiconductor) wafer,
wherein the display device further comprises:
an encapsulation layer on the light emitting element;
color filters on the encapsulation layer; and
lenses on the color filters,
wherein the display device is an OLEDoS (OLED on Silicon) display device.

11. A method comprising:
supplying a bonding assembly comprising a bonding conductive layer;
supplying a semiconductor wafer;
coupling the semiconductor wafer and the bonding assembly by the bonding conductive layer; and
patterning a light emitting element,
wherein the method is a method of manufacturing a display device.

12. The method of claim 11, wherein the supplying of the bonding assembly comprises:
forming a first base insulating layer, a second base insulating layer, and a base interlayer insulating layer on a base;
patterning an interlayer insulating layer to have different thicknesses in some areas by removing at least a portion of the base interlayer insulating layer; and
forming a base reflective conductive layer on the interlayer insulating layer,
wherein the base reflective conductive layer is formed after the interlayer insulating layer is patterned.

13. The method of claim 12, wherein the supplying of the bonding assembly further comprises:
patterning a first reflective conductive layer and a second reflective conductive layer by removing at least a portion of the base reflective conductive layer;
forming a lower conductive layer covering the first reflective conductive layer and the second reflective conductive layer; and
patterning the bonding conductive layer to comprise a first bonding conductive layer on the first reflective conductive layer and a second bonding conductive layer on the second reflective conductive layer.

14. The method of claim 13, wherein the supplying of the bonding assembly further comprises:
performing a planarization process by removing at least portions of the first bonding conductive layer and the second bonding conductive layer so that upper surfaces of the first bonding conductive layer and the second bonding conductive layer have flat surfaces that coincide with each other.

15. The method of claim 14, wherein in the coupling of the semiconductor wafer and the bonding assembly, the bonding conductive layer and the semiconductor wafer are coupled to each other by solder bonding or Cu—Cu hybrid bonding.

16. The method of claim 14, further comprising:
supplying a partition wall base by performing a back grinding process on the base after the coupling of the semiconductor wafer and the bonding assembly.

17. The method of claim 14, further comprising:
patterning partition walls that are spaced from each other and expose the first base insulating layer by removing at least a portion of the partition wall base;
forming a base partition wall insulating layer covering the partition walls and the first base insulating layer;
exposing the second base insulating layer by etching the base partition wall insulating layer and the first base insulating layer; and
exposing the interlayer insulating layer by etching the second base insulating layer.

18. The method of claim 17, wherein the light emitting element comprises an anode electrode, an emission structure, and a cathode electrode, and
wherein the patterning the light emitting element comprises:
patterning the anode electrode between the partition walls;
forming the emission structure on the anode electrode between the partition walls; and
forming the cathode electrode covering the emission structure and the anode electrode.

19. The method of claim 17, further comprising:
forming color filters on the light emitting element; and
forming lenses on the color filters.

20. An electronic device, comprising:
a processor configured to provide input image data;
a display device configured to display an image based on the input image data, the display device including sub-pixel areas; and
a power supply configured to supply power to the display device,
wherein the display device comprises:
a pixel comprising sub-pixel areas, the sub-pixel areas comprising a first sub-pixel area and a second sub-pixel area;
a semiconductor wafer comprising a substrate;
a bonding conductive layer on the semiconductor wafer;
a reflective conductive layer on the bonding conductive layer; and
a light emitting element electrically connected to the reflective conductive layer,
wherein the bonding conductive layer comprises a first bonding conductive layer in the first sub-pixel area and a second bonding conductive layer in the second sub-pixel area, and
wherein the first bonding conductive layer and the second bonding conductive layer have different thicknesses.
